(19) United States
(12) Patent Application Publication
(10) Pub. No.: US 2007/0297893 A1
(43) Pub. Date: Dec. 27, 2007

(54) Fan speed change control

(75) Inventors: Moshe Alon, Tel Aviv (IL); Nir Tasher, Tel Mond (IL); Lior Albaz, Or Yehuda (IL)

Correspondence Address: OLIFF & BERRIDGE, PLC, P.O. BOX 320850, ALEXANDRIA, VA, 22320-4850, US

(73) Assignee: Winbond Electronics Corporation, Hsinchu (TW)

(21) Appl. No.: 11/475,223

(22) Filed: Jun. 27, 2006

(51) Int. Cl. F04D 15/00; H05K 7/20

(52) U.S. Cl. 415/47; 361/695

(57) ABSTRACT

Methods and systems for controlling the speed of a fan for an electronic system. In some embodiments of the invention, temperatures are associated with changes in the value of a variable relating to fan speed. In one of these embodiments, there is a range of temperatures where the fan speed is fixed. In one embodiment of the invention, where there is a plurality of temperature readings associated with a fan, the temperature reading which would result in the highest fan speed is operative. In one embodiment of the invention, the fan speed control is capable of automatic self-adjustment.

### FIELD OF THE INVENTION

The invention relates to temperature monitoring and fan control systems.

### BACKGROUND OF THE INVENTION

Temperature control is important in many electronic systems, including, for example, computers. Fans are sometimes included in an electronic system so that the air from the fan can cool off the electronic system when necessary. In many electronic systems with fans, more frequent and/or more drastic changes in the speed of the fan result in a higher perceived noise level for the user.

### SUMMARY OF THE INVENTION

According to the present invention, there is provided: a method of controlling a speed of a fan for an electronic system comprising: determining a temperature relating to the electronic system; determining a change in a value of a variable relating to fan speed which corresponds to the determined temperature; and if there is a nonzero determined corresponding change in a value of the variable relating to fan speed, causing the speed of a fan to change in accordance with the determined corresponding change.

According to the present invention, there is also provided: a method of controlling a speed of a fan for an electronic system, comprising: determining a temperature relating to the electronic system; checking whether the temperature has a predetermined relationship with a predetermined temperature level or range; and if the temperature has a predetermined relationship, adjusting at least one parameter which affects a correspondence between temperature and change in a value of a variable relating to fan speed.

According to the present invention, there is further provided: a method of controlling a speed of a fan in an electronic system, comprising: determining a temperature relating to the electronic system; determining a temperature range which includes the determined temperature; determining a temperature direction; determining a corresponding change in duty cycle over time, or function thereof, for the determined temperature range and determined temperature direction; determining a new duty cycle based on the corresponding duty cycle change over time, or a function thereof; and outputting a PWM signal with the new duty cycle.

According to the present invention, there is still further provided: a method of controlling a speed of a fan in an electronic system, comprising: determining a plurality of temperatures relating to the electronic system which are associated with the fan; for each of the plurality of determined temperatures, calculating a value of a variable relating to fan speed or a function thereof corresponding to the each determined temperature; selecting a value of the variable or a function thereof which would lead to a highest fan speed out of the calculated values; and outputting a control signal reflecting the selection.

According to the present invention, there is provided: a method of controlling a speed of a fan for an electronic system including a central processing unit, comprising: determining a temperature relating to the electronic system; checking whether the temperature has a predetermined relationship with a predetermined temperature level or range; and if the temperature has a predetermined relationship, adjusting at least one parameter which affects fan speed; wherein the checking and adjusting occur outside of the central processing unit, and wherein the at least one parameter is selected from a group comprising: slope of a range where a variable relating to fan speed is proportional to temperature, slope of a range where duty cycle is proportional to temperature, maximum value of a variable relating to fan speed, maximum duty cycle, minimum value of a variable relating to fan speed, minimum duty cycle, predetermined level where adaptation occurs, predetermined range where adaptation occurs, predetermined relationship to be checked, impact of time duration during which a predetermined relationship holds on adaptability, correspondence between ambient temperatures and parameters, correspondence between value of a variable relating to fan speed and temperature direction, correspondence between value of a variable relating to fan speed and temperature change, correspondence between value of a variable relating to fan speed and rate of temperature change, and correspondence between value of the variable relating to fan speed with time temperature is at a same level or range.

According to the present invention, there is also provided: a system for controlling a speed of a fan for an electronic system, comprising: a temperature monitoring and fan control module, wherein the temperature monitoring and fan control module is configured to receive temperature readings relating to the electronic system, configured to determine changes in the values of at least one variable which correspond to the temperature readings, and configured to generate control signals capable of causing a fan to change or maintain speed in accordance with the determined changes.

According to the present invention, there is further provided: a system for controlling a speed of a fan for an electronic system, comprising: a temperature monitoring and fan control module, wherein the temperature monitoring and fan control module is configured to receive temperature readings relating to the electronic system, configured to check whether a received temperature reading has a predetermined relationship with a predetermined temperature level or range; and configured to adjust at least one parameter which affects a correspondence between temperature and change in the value of a variable relating to fan speed, if the received temperature reading has a predetermined relationship.

According to the present invention, there is provided: a system for controlling a speed of a fan for an electronic system, comprising: means for determining a temperature relating to the electronic system; means for determining a temperature range which includes the determined temperature; means for determining a temperature direction; means for determining a corresponding change in duty cycle over time, or function thereof, for the determined temperature range and determined temperature direction; means for determining a new duty cycle based on the corresponding duty cycle change over time, or a function thereof; and means for outputting a PWM signal with the new duty cycle.

According to the present invention, there is also provided: a system for controlling a speed of a fan for an electronic system, comprising: a temperature monitoring and fan control module, wherein the temperature monitoring and fan control module is configured to receive a plurality of temperature readings relating to the electronic system associated with a fan, configured for each of the plurality of received temperatures to calculate a value of a variable relating to fan speed or a function thereof corresponding to the each received temperature; configured to select a value of a variable or a function thereof which would lead to a highest fan speed out of the calculated values; and configured to output a control signal reflecting the selection.

According to the present invention, there is further provided: a system for controlling a speed of a fan for an electronic system including a central processing unit, comprising: a temperature monitoring and fan control module, external to the central processing unit, configured to receive a temperature relating to the electronic system; configured to check whether the temperature has a predetermined relationship with a predetermined temperature level or range; and configured to adjust at least one parameter which affects fan speed, if the temperature has a predetermined relationship; wherein the at least one parameter is selected from a group comprising: slope of a range where a variable relating to fan speed is proportional to temperature, slope of a range where duty cycle is proportional to temperature, maximum value of a variable relating to fan speed, maximum duty cycle, minimum value of a variable relating to fan speed, minimum duty cycle, predetermined level where adaptation occurs, predetermined range where adaptation occurs, predetermined relationship to be checked, impact of time duration during which a predetermined relationship holds on adaptability, correspondence between ambient temperatures and parameters, correspondence between value of a variable relating to fan speed and temperature direction, correspondence between value of a variable relating to fan speed and temperature change, correspondence between value of a variable relating to fan speed and rate of temperature change, and correspondence between value of the variable relating to fan speed with time temperature is at a same level or range.

According to the present invention, there is provided: a computer program product comprising a computer useable medium having computer readable program code embodied therein for controlling a speed of a fan for an electronic system the computer program product comprising: computer readable program code for causing the computer to determine a temperature relating to the electronic system; computer readable program code for causing the computer to determine a change in a value of a variable relating to fan speed which corresponds to the determined temperature; and computer readable program code for causing the computer to cause the speed of a fan to change in accordance with the determined corresponding change, if there is a nonzero determined corresponding change in a value of the variable relating to fan speed.

According to the present invention, there is also provided: a computer program product comprising a computer useable medium having computer readable program code embodied therein for controlling a speed of a fan for an electronic system, the computer program product comprising: computer readable program code for causing the computer to determine a temperature relating to the electronic system; computer readable program code for causing the computer to check whether the temperature has a predetermined relationship with a predetermined temperature level or range; and computer readable program code for causing the computer to adjust at least one parameter which affects a correspondence between temperature and change in a value of a variable relating to fan speed, if the temperature has a predetermined relationship.

According to the present invention, there is further provided: a computer program product comprising a computer useable medium having computer readable program code embodied therein for controlling a speed of a fan in an electronic system, the computer program product comprising: computer readable program code for causing the computer to determine a temperature relating to the electronic system; computer readable program code for causing the computer to determine a temperature range which includes the determined temperature; computer readable program code for causing the computer to determine a temperature direction; computer readable program code for causing the computer to determine a corresponding change in duty cycle over time, or function thereof, for the determined temperature range and determined temperature direction; computer readable program code for causing the computer to determine a new duty cycle based on the corresponding duty cycle change over time, or a function thereof; and computer readable program code for causing the computer to output a PWM signal with the new duty cycle.

According to the present invention, there is still further provided: a computer program product comprising a computer useable medium having computer readable program code embodied therein for controlling a speed of a fan in an electronic system, the computer program product comprising: computer readable program code for causing the computer to determine a plurality of temperatures relating to the electronic system which are associated with the fan; computer readable program code for causing the computer to calculate a value of a variable relating to fan speed or a function thereof corresponding to the each determined temperature for each of the plurality of determined temperatures; computer readable program code for causing the computer to select a value of the variable or a function thereof which would lead to a highest fan speed out of the calculated values; and computer readable program code for causing the computer to output a control signal reflecting the selection.

According to the present invention, there is yet further provided: a computer program product comprising a computer useable medium having computer readable program code embodied therein for controlling a speed of a fan for an electronic system including a central processing unit, the computer program product comprising: computer readable program code for causing the computer to determine a temperature relating to the electronic system; computer readable program code for causing the computer to check whether the temperature has a predetermined relationship with a predetermined temperature level or range; and computer readable program code for causing the computer to adjust at least one parameter which affects fan speed, if the temperature has a predetermined relationship; wherein the checking and adjusting occur outside of the central processing unit, and wherein the at least one parameter is selected from a group comprising: slope of a range where a variable relating to fan speed is proportional to temperature, slope of a range where duty cycle is proportional to temperature, maximum value of a variable relating to fan speed, maximum duty cycle, minimum value of a variable relating to fan speed, minimum duty cycle, predetermined level where adaptation occurs, predetermined range where adaptation occurs, predetermined relationship to be checked, impact of time duration during which a predetermined relationship holds on adaptability, correspondence between ambient temperatures and parameters, correspondence between value of a variable relating to fan speed and temperature direction, correspondence between value of a variable relating to fan speed and temperature change, correspondence between value of a variable relating to fan speed and rate of temperature change, and correspondence between value of the variable relating to fan speed with time temperature is at a same level or range.

### BRIEF DESCRIPTION OF THE DRAWINGS

In order to understand the invention and to see how it may be carried out in practice, a preferred embodiment will now be described, by way of non-limiting example only, with reference to the accompanying drawings, in which:

FIG. 1 is a block diagram of a system for fan control, according to an embodiment of the present invention;

FIG. 2 is a block diagram of a temperature monitoring and fan control module, according to an embodiment of the present invention;

FIG. 3 is a flowchart of a method for controlling fan speed, according to an embodiment of the present invention;

FIG. 4 is a flowchart of a method for controlling fan speed which includes adjustable parameters, according to an embodiment of the present invention;

FIG. 5 is a bubble diagram of a fan control algorithm, according to an embodiment of the present invention;

FIG. 6 illustrates two examples of the algorithm of FIG. 5 over time plotted on a graph of duty cycle versus temperature, according to an embodiment of the present invention;

FIG. 7 is a flowchart of a method for controlling the fan speed where there are multiple temperature measurements, according to this embodiment of the present invention;

FIG. 8 is a block diagram of a circuit for a fan driver, according to an embodiment of the present invention;

FIG. 9 is an example of another algorithm with adjustable parameters, according to an embodiment of the present invention; and

FIG. 10 is a flowchart of a method for controlling the fan speed which includes adjustable parameters, using the algorithm of FIG. 9, according to an embodiment of the present invention.

### DETAILED DESCRIPTION OF EXEMPLARY EMBODIMENTS

Described herein are embodiments of the current invention for fan speed control.

As used herein, the phrase “for example,” “such as” and variants thereof describing exemplary implementations of the present invention are exemplary in nature and not limiting.

The term change as used herein should be construed to include zero and/or non-zero change, as appropriate. A nonzero change can be positive and/or negative, as appropriate.

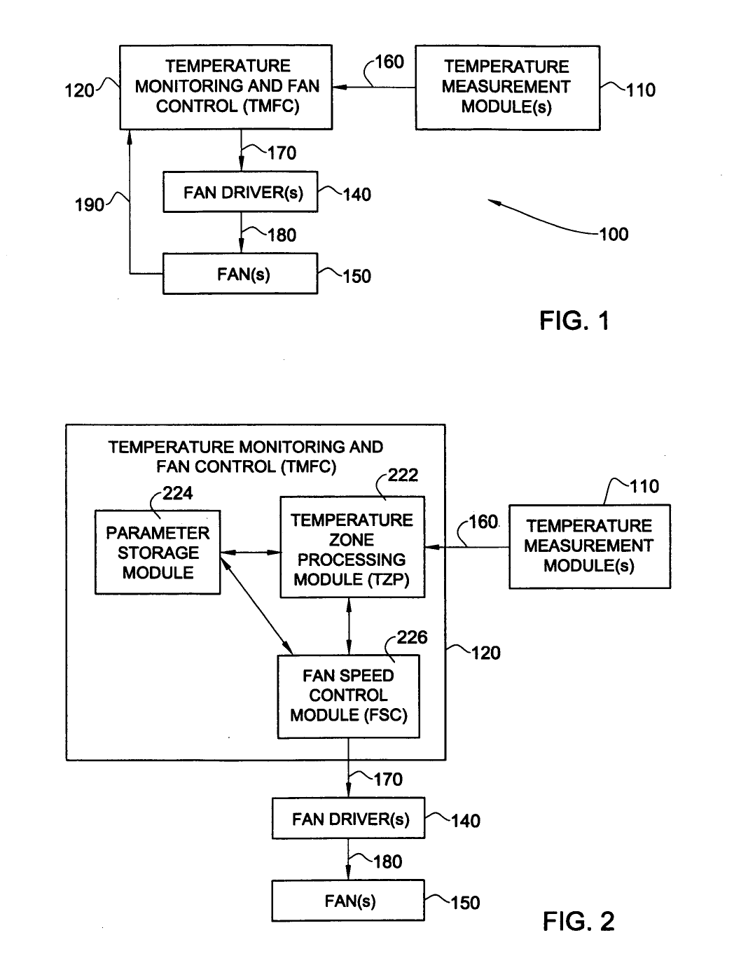

Refer to FIG. 1 which shows a system 100 for fan speed control, according to an embodiment of the present invention. In one embodiment, parts or all of system 100 can be placed anywhere within and/or outside an electronic system in order to attempt to control the temperature of the electronic system. The illustrated system 100 includes one or more temperature measurement module(s) 110, a temperature monitoring and fan control module TMFC 120, one or more fan driver(s) 140 and one or more fans 150. Each of temperature measurement module(s) 110, temperature monitoring and fan control module 120, fan driver(s) 140 and fan(s) 150 may be made up of any combination of software, hardware and firmware that performs the functions as defined and explained herein.

In some embodiments, temperature measurement module(s) 110, may be arranged to measure temperature at one or more points or zones in the electronic system. For example, in one of these embodiments, the one or more zones may include inter-alia one or more zones in the central processing unit CPU. Examples of temperature zone measurements include one or more of the following inter-alia: ambient temperature measurement, memory temperature measurement, power supply temperature measurement, and chip set components temperature measurement. In one embodiment, there may in some cases be more than one type of measurement module 110, for example which use different types of interfaces. The interfaces can be digital and/or analog. For example interfaces in this embodiment can include one or more of the following inter-alia: SMBus External Interface, Platform Environmental Control Environment PECI, AMD Serial Interface, thermal diode, a temperature driven interface that sets a voltage and/or current level, an interface that sets a resistance capacitance of induction at the interface, etc. Examples of commercially available sensor devices which may be used as temperature measurement module 110 include inter-alia National Semiconductor LM92 and/or LM95221, available from National Semiconductor Corp., headquartered in Santa Clara, Calif., and W83L771W available from Winbond Electronics Corp. headquartered in Hsinchu, Taiwan.

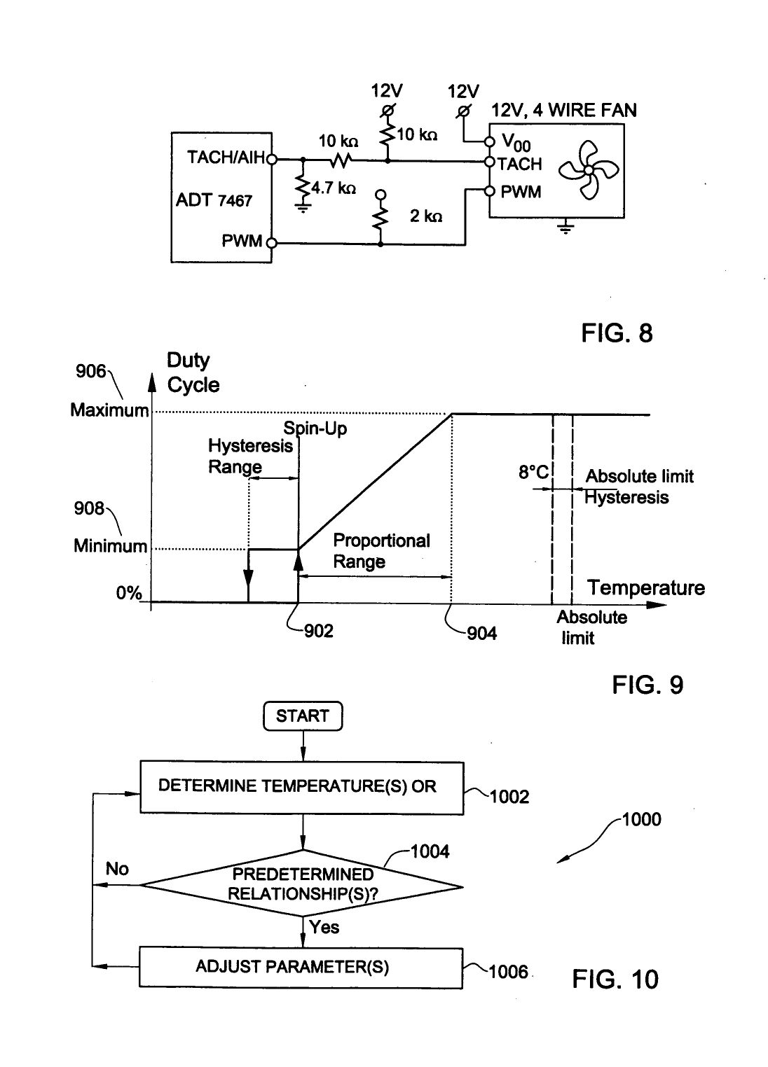

Examples of commercially available fans that can be used as fan 150 include inter-alia Fanner MASSCOOL SF263B1M3 AMD XP/MP/Duraon CPU Fan, available from Fanner Tech USA Corp., headquartered in City of Industry, Calif.; and Panaflo Fan Model P80 1A series (4 wire option) available from Panasonic (Matsushita Electric Industrial Co., Ltd), headquartered in Japan. One example of a fan driver which can be used as fan driver 140 is illustrated in FIG. 8. The fan driver illustrated in FIG. 8 is configured to drive a four-wire fan with a high frequency PWM, for example Panaflo Fan Model P80 1A series.

In some embodiments, system 100 may comprise fewer, more or different components than those shown in FIG. 1. Depending on the embodiment, system 100 may be concentrated in one enclosure, located in more than one enclosure in proximity of one another, or distributed in more than one location. For example in one embodiment, TMFC 120, temperature measurement module(s) 110, fan driver(s) 140, and fan(s) 150 may be implemented on the same integrated circuit or on a combination of different integrated circuits. As another example in one embodiment the components illustrated in FIG. 1 as being connected by lines are coupled to one another either through a direct electrical connection or indirectly through one or more intermediary active or passive elements. As another example, the functionality of some or all of temperature measurement module(s) 110 and/or TMFC 120, may be within or outside the CPU of the electronic system.

FIG. 2 illustrates the modules which comprise temperature TMFC 120, according to an embodiment of the present invention. In the illustrated embodiment, TMFC 120 includes a temperature zone processing TZP module 222 configured to interface with temperature measurement module(s) 110 and calculate the appropriate value for a variable relating to fan speed, a parameter storage module 224 configured to provide parameter(s) used in controlling the fan speed, and a fan speed control FSC module 226 configured to control the fan speed. Each of modules 222, 224, and 226 may be made up of any combination of software, hardware and firmware that performs the functions as defined and explained herein. For example in one embodiment, parameter storage module 224 includes inter-alia one or more configuration registers. For example in one embodiment, parameter storage module includes inter-alia one or more correspondence tables which include the correspondence among one or more of the following: temperatures, temperature ranges, temperature directions, time, changes in temperatures, rate of change (deviation) of temperature, variable values, changes in variable values, etc.

The division of TMFC 120 into the modules shown in FIG. 2 is for ease of explanation but in some embodiments TMFC 120 may comprise fewer, more or different modules than those shown in FIG. 2. For example in one embodiment, TMFC 120 also includes a fan speed monitoring module FSM which receives feedback from fan(s) 150, for example tachometer inputs in order to check that fan(s) 150 have not stalled. As another example, in one embodiment the functionality of modules 222, 224, and 226 may be provided by fewer, more or different modules than those shown in FIG. 2 and/or the functionality may be divided differently among modules 222, 224 and 226. Continuing with the example some or all of the functionality discussed below for TZP 222 may in other embodiments be performed by FSC 226, and/or some or all of the functionality discussed below for FSC 226 may be performed in other embodiments by TZP 222.

Depending on the embodiment, the modules comprising TMFC 120 may be concentrated or distributed. Depending on the embodiment, the modules comprising TMFC 120 may be placed in any suitable location. For example, assuming the electronic system is a personal computer, TMFC 120 can be for example on the motherboard or for example can be an embedded controller. As another example, TMFC 120 can be implemented on any component related to the electronic system.

In operation, TZP 222 receives temperature readings 160 and possibly other data from temperature measurement module(s) 110. Based on the received temperature readings 160 and/or corresponding parameters stored in parameter storage module 224, TZP 222 performs any necessary calculation (described below) in order to determine the value of a variable relating to fan speed. The variable value is provided by TZP 222 to FSC 226 which in turn provides corresponding control signal(s) 170 to fan driver(s) 140. Fan driver(s) 140 provides corresponding control signal(s) 180 to fan(s) 150. In one embodiment, with a 4 wire fan, control signal(s) 170 and control signal(s) 180 are identical.

Fan(s) 150 may be driven through any appropriate method. In some embodiments, the variable value provided to FSC 226 is the fan duty cycle. In one of these embodiments FSC 226 includes one or more circuits to generate pulse width modulation PWM signals with a duty cycle corresponding to the duty cycle provided by TZP 222 or to a function of the provide duty cycle, and control signals 170 (outputted by FSC 226) include pulse width modulation PWM signals. As is known in the art, the duty cycle is a value typically given in a percentage which reflects the percentage of time a signal is at a high level over a single pulse time frame. As is also known in the art, pulse-width modulation of a signal or power source involves the modulation of its duty cycle, to either convey information over a communications channel or control the amount of power sent to a load. As is also known in the art, a higher duty cycle for a PWM signal translates into a higher fan speed. Circuits to generate PWM signals are known in the art and will therefore not be further discussed.

In other embodiments, fan(s) 150 control may also or instead be implemented by controlling other variables relating to fan speed or functions thereof, for example voltage levels and/or current levels. In these embodiments, FSC 226 is configured to control for example the voltage level and/or current level based on a variable value provided to FSC 226. For example, in one of these embodiments, the variable value provided to FSC 226 is the voltage level and/or current level and FSC 226 outputs the voltage and/or current level. As another example, in one of these embodiments, the variable value provide to FSC 226 is the duty cycle, and FSC 226 translates the duty cycle into voltage and/or current level and outputs the voltage and/or current level. Although for ease of explanation, most of the embodiments of the invention described below refer to FSC 226 being provided duty cycles and outputting PWM signals with the provided duty cycles, it should be evident to the reader that in other embodiments other variables relating to fan speed may be provided to FSC 226 and/or FSC can output other control signals, and in these other embodiments similar methods and systems to those described below can be used, mutatis mutandis.

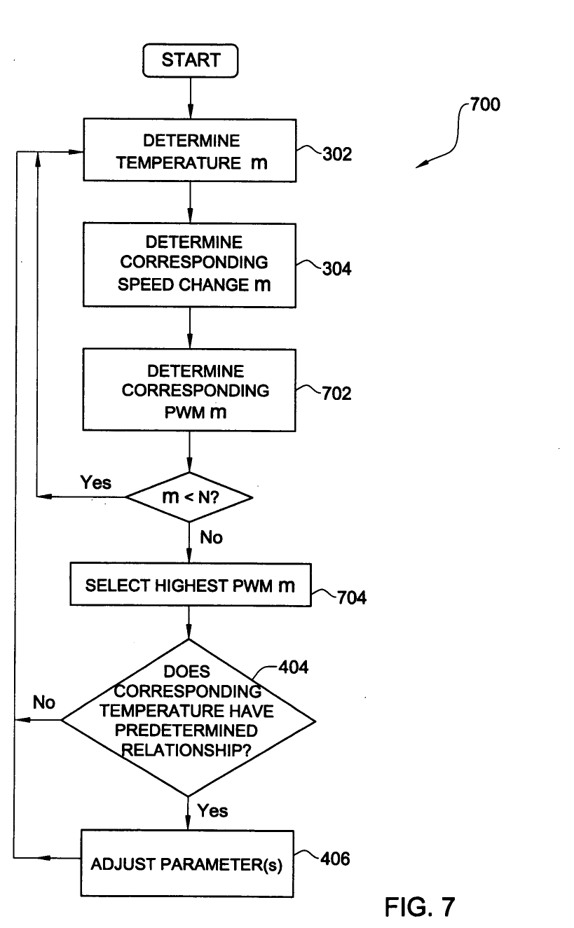

In some embodiments, there is feedback from FSC 226 to TZP 222, and in other embodiments no feedback is required. For example in embodiments with a plurality of temperature readings 160, FSC 226 may in one of these embodiments indicate to TZP 222 the selected duty cycle (the selected other variable relating to fan speed, and/or function thereof) and/or corresponding temperature so that TZP 222 can perform, if necessary, adaptation of parameters, and in another embodiment FSC 226 may not need to indicate to TZP 222 the selected duty cycle (selected other variable relating to fan speed, and/or function thereof) and/or corresponding temperature, for example if the embodiment does not include parameter adaptation or if adaptation does not depend on which duty cycle (other variable relating to fan speed, and/or function thereof) was selected—see below with reference to FIG. 7 for more details.

In one embodiment of the invention the received temperature readings 160 may be low pass filtered in order to prevent temperature spikes from impacting on control signals 170 and possibly causing unnecessary unpleasant noise. Therefore in the description here when referring to measured temperature, received temperature, temperature reading, determined temperature, temperature 160, or similar terms, the reader should understand these terms to encompass both an embodiment where the temperature is low pass filtered and an embodiment where the temperature is not low pass filtered.

Depending on the embodiment, TMFC 120 may operate in one or more modes. In some embodiments of the invention, the one or more modes includes a mode where temperatures correspond to predefined changes in the values of a variable relating to fan speed rather than directly to predefined fan speeds (or rather than directly to predefined values of a variable relating to fan speed), as will be elaborated on below. The correspondence between the changes in the values of the variable relating to fan speed and various temperatures may be stored for example in parameter storage 224. In some of these embodiments, the change in the variable relating to fan speed is over a period of time, thus controlling the fan speed in the time domain. These embodiments where the variable is changed over a period of time, may in some cases advantageously result in a reduced level noise (compared to a mode where temperatures correspond directly to fan speeds or to values of a variable relating to fan speed) because the fan speed change is gradual.

In some embodiments where temperatures correspond to predefined changes in the values of a variable relating to fan speed, there are one or more ranges of temperatures where the corresponding change(s) in the value of the variable relating to fan speed is zero, hence the fan speed is constant, which in some cases may be advantageous in terms of reduced noise for temperatures in those range(s).

In some embodiments, the fan control algorithm is adjustable as will be described in more detail below. For example, one or more of the parameters in storage module 224 may in this embodiment be adapted based on temperature readings 160. This adaptability may in some cases be advantageous in allowing TMFC 120 to calibrate itself so as to be able to function in different types of environments, and/or in varying environments (i.e. where the ambient temperature is not stable). For example, the adaptability may allow calibration in extreme environments without compromising operation under regular conditions. In some of these cases, TMFC 120 can calibrate itself independently of the host of the electronic system whose temperature is being controlled.

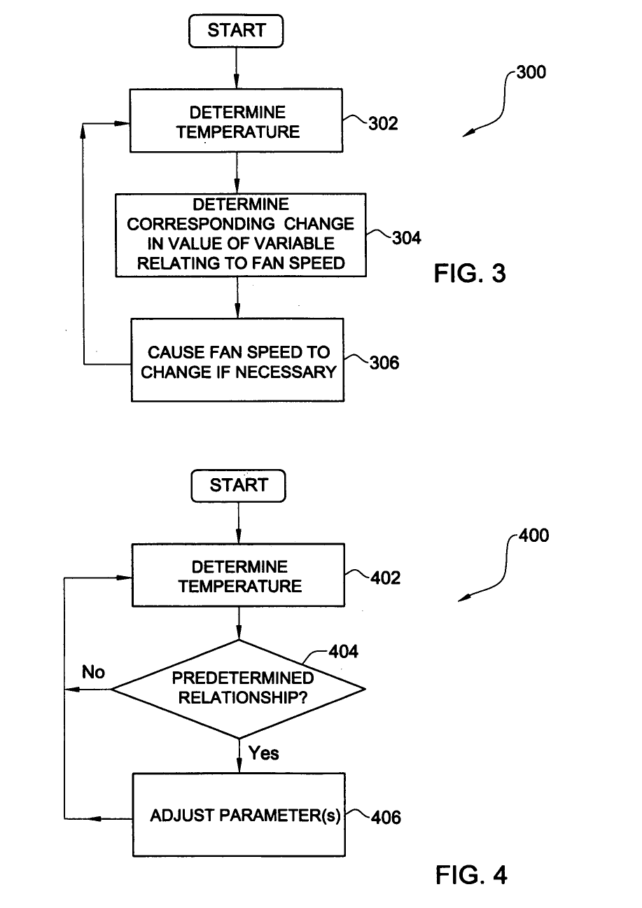

Refer to FIG. 3 which shows a method 300 of controlling fan speed in the mode where the temperature corresponds to a change in the value of a variable relating to fan speed, according to an embodiment of the present invention. Method 300 will be described in conjunction with the modules of TMFC 120 illustrated in FIG. 2. In other embodiments, method 300 may include fewer, more or different stages than those illustrated in FIG. 3, the order of stages may differ from the order in FIG. 3, and/or one or more stages may be executed simultaneously.

It is assumed for ease of description of method 300 that only one temperature measurement module 110 is used, measuring one temperature zone. Later in the description, the usage of more than one temperature measurement module 110 and/or more than one temperature zone will be elaborated on. It is also assumed for ease of explanation that there is only one fan 150 or that all fan(s) 150 are driven with the same control signals 180, therefore only a single fan 150 is described. As is known to the reader, even if all fans 150 are driven with the same control signals 180, for example representing the same duty cycle, the fans may not necessarily rotate at the same speed, but this does not impact on the invention. Later in the description this constraint of a single fan and/or identical control signals 180 will be relaxed.

In stage 302, the temperature is determined by TZP 222. For example TZP 222 may receive a temperature measurement 160 from temperature measurement module 110. In stage 304, the corresponding change in value of the variable relating to fan speed is determined. For example, TZP 222 can retrieve from storage module 224 the change in value (where the change can be zero or nonzero) of the variable relating to fan speed corresponding to temperature 160. As another example, TZP 222 can determine the corresponding change in value of the variable relating to fan speed by processing the values of one or more stored parameters retrieved from storage module 224. TZP 222 then calculates the value of the variable after subtraction or addition of the change. If the corresponding change in the value of the variable is zero, then the calculated value of the variable remains constant. In stage 306, FSC 226 receives the calculated value of the variable from TZP 222 and outputs control signals 170 which cause fan 150 to change speed if necessary or to maintain speed. For example, in one embodiment FSC 226 may receive the calculated value of the duty cycle which incorporates any change in the duty cycle corresponding to temperature, and FSC 222 may output a PWM signal whose duty cycle is the received duty cycle or a function thereof. As mentioned above it is advantageous, if the change in the value of the variable is implemented over a period of time, and in this case stages 304 and 306 may be repeated over the period of time. Continuing with this embodiment if the duty cycle is to be changed over a period of time, then during the period of time TZP 222 may continuously calculate the new duty cycle (stage 304), FSC 222 may receive the calculated new duty cycle, and FSC 222 may output a PWM signal whose duty cycle is the received duty cycle or a function thereof (stage 306). In other embodiments, another variable relating to fan speed, for example current level and/or voltage level, may instead or in addition be calculated.

Method 300 repeats as long as temperature monitoring is desirable (for example in one embodiment method 300 repeats as long as the electronic system whose temperature is controlled by system 100 is on).

In some embodiments, there is a required relationship between positive speed changes (acceleration) and negative speed changes (deceleration) allowed by system 100. For example for each positive speed change there is a negative speed change of the same amount. As another example, certain positive (negative) speed changes may be multiples of certain negative (positive) speed changes. In other embodiments there is no required relationship between positive speed changes and negative speed change, however in some of these other embodiments there may be constraints. For example in one of these other embodiments, allowed positive speed changes are equal or larger than allowed negative speed changes for a given system 100, so as to prevent system damage. Similarly, the positive and negative changes in the values of the variable relating to fan speed may or may not have a required relationship depending on the embodiment.

In one embodiment of the invention, there is no required direct correspondence between temperature and fan speed (or between temperature and a variable relating to fan speed) in addition to the correspondence between temperature and the change in value of a variable relating to fan speed. In other words, in this embodiment a given temperature corresponds to a change in the value of a variable relating to fan speed but not to one particular (target) fan speed nor to one particular (target) variable value, and therefore a given temperature may at different times result in different values of the variable and/or different fan speeds.

In some embodiments of the invention, as part of stage 302, TZP 222 determines a temperature range which includes the determined temperature. For example, the correspondence between temperatures and temperature ranges may be stored in parameter storage module 224 and retrieved by TZP 222. In another embodiment, TZP 222 can determine the temperature range which includes the determined temperature by processing the values of one or more stored parameters retrieved from storage module 224. In some of these embodiments, the correspondence between a given temperature and the corresponding change in the value of a variable relating to fan speed is expressed as a correspondence between the temperature range including the given temperature and the corresponding variable value change. For example, in stage 304, TZP 222 can retrieve from storage module 224 the change in the value of the variable relating to fan speed which corresponds to the temperature range which includes the given temperature. As another example, TZP 222 can determine the change in the variable relating to fan speed corresponding to the temperature range, by processing the values of one or more stored parameters retrieved from storage module 224.

In some embodiments of the invention, there are temperatures which correspond to zero (no) change in the value of the variable relating to fan speed, hence maintaining the fan speed. Therefore in these embodiments, if the determined temperature corresponds to no change in the value of the variable relating to fan speed, then in stage 306, FSC 226 outputs control signals 170 which cause fan 150 to maintain speed. In some of these embodiments, there are one or more temperature ranges which correspond to no change in the value of the variable relating to fan speed, hence maintaining the fan speed. In one of these embodiments, the actual speed which is to be maintained is not predefined and is instead equal to the speed of fan(s) 150 when the temperature is first determined as being in a temperature range which corresponds to zero speed change.

In some embodiments of the invention, the corresponding change in the value of the variable relating to fan speed (determined in stage 304), also or instead depends on the temperature direction. In some of these embodiments, the corresponding change in the value of the variable relating to fan speed may be different for the same temperature depending on whether the temperature is rising or falling (for example compared to the temperature determined in the previous execution round of stage 302). For example in some of these embodiments, for certain given temperatures, a rising direction in temperature corresponds to a larger change in the value of the variable relating to fan speed than a falling direction in temperature because the overheating of an electronic system poses a greater danger than the overcooling. In these embodiments, allowing a delayed response for system cooling may in some cases be advantageous because of reduced fan speed changes and thus reduced perceived noise. Some of these embodiments where temperature direction is a factor may also express the correspondence between a given temperature and the corresponding change in the value of the variable relating to speed as a correspondence between the temperature range including the given temperature (taking into account the temperature direction) and the corresponding variable value change.

In some embodiments of the invention, the corresponding change in the value of the variable relating to fan speed, also or instead depends on the change in temperature. For example, TZP 222 calculates the temperature change from the temperature determined in the previous execution round of stage 302. Continuing with this example, in one of these embodiments, there may be a plurality of possible corresponding changes in value of the variable relating to fan speed for each temperature or temperature range and depending on how large the change in temperature, TZP 222 picks the appropriate corresponding change in value of the variable relating to fan speed.

In some embodiments of the invention, the corresponding change in the value of the variable relating to fan speed, also or instead depends on the rate of change (deviation) in temperature. For example, TZP 222 calculates the rate of temperature change (i.e. how fast the temperature has changed over a given period). Continuing with this example, in one of these embodiments, there may be a plurality of possible corresponding changes in value of the variable relating to fan speed for each temperature or temperature range and depending on how large the rate of temperature change, TZP 222 picks the appropriate corresponding change in value of the variable relating to fan speed.

In some embodiments of the invention, there may be a plurality of possible corresponding changes in value of the variable relating to fan speed for each temperature or temperature range, and TZP 222 picks the appropriate corresponding change based on the amount of time that the determined temperature (stage 302) has remained at the same temperature or within the same temperature range.

In some embodiments, the selection from among more than one corresponding changes in value of the variable relating to fan speed for each temperature or temperature range may be based on a combination of factors, including inter-alia: change in temperature, rate of temperature change, temperature direction, time duration, etc.

FIG. 4 illustrates a method 400 of controlling the fan speed, where parameters impacting on the correspondence between temperature and change in the value of the variable relating to fan speed are adjustable, according to an embodiment of the invention. When discussing here and below parameters affecting the correspondence between temperature and change in the variable relating to fan speed, it should be understood that the discussed correspondence includes any type of correspondence with temperature, including correspondence with one or more of the following inter-alia: temperature, temperature range including temperature, temperature direction, change in temperature, rate of change in temperature, time that temperature has remained the same or within the same temperature range, etc. Method 400 will be described in conjunction with the modules of TMFC 120 illustrated in FIG. 2. Depending on the embodiment, method 400 may be implemented for system 200 with or without method 300. In other embodiments, method 400 may include fewer, more or different stages than those illustrated in FIG. 4, the order of stages may differ from the order in FIG. 4, and/or one or more stages may be executed simultaneously.

It is assumed for ease of description of method 400 that only one temperature measurement module 110 is used. Later in the description, the usage of more than one temperature measurement module 110 will be elaborated on. It is also assumed for ease of explanation that all fan(s) 150 operate at the same speed and/or there is only one fan 150 and therefore only a single fan 150 is described. Later in the description this constraint will be relaxed.

In stage 402, the temperature is determined by TZP 222. For example TZP 222 may receive a temperature measurement 160 from temperature measurement module 110. In some embodiments, stage 402 is identical to stage 302. In stage 404, it is determined whether the temperature has one or more predetermined relationship(s) with one or more predetermined temperature levels and/or one or more predetermined temperature ranges. For example in one embodiment, checking whether the temperature has one or more predetermined relationship with predetermined temperature level(s)/range(s) and acting accordingly, improves the temperature control provided by system 100. For simplicity of description, it is assumed that there is one predetermined relationship and one predetermined temperature level which should be checked. Depending on the embodiment, the determination in stage 404 may be whether the temperature is at a predetermined level, at or below a predetermined level, at or above a predetermined level, below a predetermined level, above a predetermined level, or having any predetermined relationship with a predetermined temperature level. The predetermined temperature level may be any appropriate level and the predetermined relationship may be any appropriate relationship. If the determination is that the measured temperature has a predetermined relationship with a predetermined level, then in stage 406, one or more parameters affecting the correspondence between temperature and the change in the value of the variable relating to fan speed are adjusted. With or without adjustment, method 400 repeats as long as temperature monitoring is desirable (for example in one embodiment method 400 repeats as long as the electronic system whose temperature is controlled by system 100 is on).

For example in one embodiment, the predetermined level is based on (i.e. a function of) an “absolute limit” temperature which is considered the hottest allowable temperature for the electronic system whose temperature is being controlled. The decision of what is the “hottest” permissible may vary depending on the electronic system and/or other factors. Continuing with this example, the predetermined level may be a certain number of degrees, say 3 degrees Celsius to 5 degrees Celsius, below the absolute limit. Still continuing with the example, in stage 404 it can be checked whether the temperature is at or above the predetermined level and if yes, one or more parameters may be adjusted, for example so that the temperature is less likely to continue to rise high enough to reach the absolute limit and/or so that in the future the temperature is less likely to reach the predetermined level. It should be evident to the reader, that in another embodiment the same limitation could be checked by defining the absolute limit as the predetermined level and the predetermined relationship as “at or above 3 to 5 degrees Celsius below the predetermined level”

In some embodiments, one or more parameters impacting on the correspondence between temperature and change in the value of the variable relating to fan speed can be adjusted, making higher temperatures more likely. For example, a table of minimum and/or maximum values for one more parameters corresponding to ambient temperatures can be set. As another example a table recording the historical correspondence between minimum and/or maximum values of one or more parameters and ambient temperature may be maintained. This historical table can be updated in some embodiments on the fly. In either of these examples, in stage 404, if the temperature has not reached a predetermined level during a predetermined period of time, and the electronic system is on (i.e. not off or sleeping), then one or more parameters can be adjusted in stage 406, so that the temperature is more likely to reach the predetermined level. In one embodiment, the predetermined level is based on the “absolute limit” temperature, for example a certain number of degrees, say 3 degrees Celsius to 5 degrees Celsius below the absolute limit. In one embodiment, the adjustment takes into account the set and/or historical correspondence with the ambient temperature. For example, assuming a certain ambient temperature value, the acceleration level may be allowed to drop a certain amount lower than the set and/or historical value of the acceleration level achieved when the temperature exceeded the predetermined level and the ambient temperature equaled that certain value. By taking the ambient temperature into account, this embodiment prevents the ambient temperature from exercising an inordinate influence on the fan speed.

In another embodiment, there may be one or more temperature ranges (instead of or in addition to levels) and the predetermined relationship may be whether a determined temperature is within one or more of those ranges. In this embodiment, if the determined temperature is determined to be in these one or more ranges (in stage 404), then one or more parameters impacting on the correspondence between temperature and changes in the values of the variable relating to fan speed are adjusted in stage 406. For example, assuming a plurality of temperature ranges, in one embodiment, there is an adaptation of one or more parameters for each range. If there are different ranges, in some embodiments there is no required relationship between which parameters are adapted and/or how the parameters are adapted for each range. For example in one of these embodiments, there may be for example two temperature ranges where the corresponding change in the value of the variable relating to fan speed is adjusted for example to become higher. Continuing with the example, if the determined temperature reaches the lower temperature range, there may be a first adaptation where the change becomes higher and if the determined temperature reaches a higher temperature range, there may be a second additional adaptation where the change becomes higher. Similarly there may be a plurality of temperature ranges where the corresponding change in the value of the variable relating to fan speed is adjusted to become lower.

In some embodiments, the amount of time which the temperature has a predetermined relationship(s) with a predefined level(s)/temperature range(s) impacts on the adaptation in stage 406 of one or more parameters affecting the correspondence between temperature and changes in the values of the variable relating to fan speed. The impact can be for example on which parameter(s) are adapted and/or on how the parameter(s) are adapted. For example in some of these embodiments, the change in the value of the variable relating to fan speed may be defined so that the longer the temperature has a predetermined relationship with predefined level(s)/temperature range(s), the higher the acceleration (or the slower the deceleration) corresponding to at least one temperature. Continuing with the example, in one of these embodiments for each consecutive sampling (i.e. repetition of stage 402) where the temperature is determined in stage 404 to have the predefined relationship with predefined level(s)/range(s), the change in value is redefined in stage 406, causing, for example, an increased acceleration (or a decreased deceleration) corresponding to at least one temperature. Similarly the change in the value of the variable relating to fan speed may be defined so that the longer the temperature has a predetermined relationship with predefined level(s)/range(s), the lower the acceleration (or the higher the deceleration) corresponding to at least one temperature.

In some embodiments, the change in determined temperature, for example from the temperature determined in the previous execution round of stage 402 may be calculated by TZP 222 and may in some cases affect the adaptation in stage 406 of one or more parameters which impact on the correspondence between temperature and changes in the values of the variable relating to fan speed. For example in one of these embodiments, which parameter(s) are adapted and/or how the parameters are adapted may depend on the change in temperature.

In some embodiment, the temperature direction, for example from the temperature determined in the previous execution round of stage 402 may be determined by TZP 222 and may in some cases affect the adaptation in stage 406 of one or more parameters which impact on the correspondence between temperature and changes in the values of the variable relating to fan speed. For example in one of these embodiments, which parameter(s) are adapted and/or how the parameters are adapted may depend on the temperature direction.

In some embodiments, the rate of change (deviation) in determined temperature may be calculated by TZP 222 and may in some cases affect the adaptation in stage 406 of one or more parameters which impact on the correspondence between temperature and changes in the values of the variable relating to fan speed. For example in one of these embodiments, which parameter(s) are adapted and/or how the parameters are adapted may depend on the temperature deviation.

In some embodiments, which of a plurality of predetermined relationships holds between said determined temperature and predefined level(s)/range(s) impacts on the adaptation in stage 406 of one or more parameters affecting the correspondence between temperature and changes in the values of the variable relating to fan speed. For example, one predetermined relationship can be whether at a predetermined level, another whether 1 degree above (or below) the level, and a third whether 2 degrees above (or below) the level, and depending on which predetermined relationship holds, the adaptability is varied.

The amount of adjustment of any parameters in stage 406 may be determined in any appropriate way. For example, in various embodiments the amount of adjustment may be stored and retrieved from parameter storage 224 and/or calculated using a table and/or another function, etc.

There is no limitation on how many parameters are adjusted, which parameters are adjusted, how the parameters are adjusted, how many times the parameters are adapted, etc. and any of these can vary depending on the embodiment. Examples of parameters which can be adjusted include inter-alia one or more of the following: change in the value of the variable relating to fan speed in one or more temperature ranges; the upper and/or lower bounds of one or more temperature ranges, predetermined level(s) and/or range(s) where adaptation occurs, predetermined relationship(s) to be checked, the impact the time during which predetermined relationship(s) holds on adaptability, the correspondence between the change in the value of the variable relating to fan speed with temperature (including one or more of: temperature, temperature direction, temperature change, temperature range, rate of change in temperature, time temperature is at the same level or within same range, etc), and correspondence between parameters and ambient temperature.

The change in the variable relating to fan speed can be expressed in any suitable format which can be processed by TMFC 120. Assume embodiments where changes in the variable are over a period of time. Further assume as an example embodiments where control signals 170 include one or more PWM signals and changes in the value of the variable relating to fan speed impacts on the duty cycle of the PWM signals. In some of these embodiments, a nonzero change in the value of the variable may be expressed as a step that defines the change in the duty cycle during a predefined period of time, and/or may be expressed as a step that defines the period during which the duty cycle changes by a certain amount. For ease of description it is assumed below that control signals 170 are PWM signals and that a nonzero change in the value of the variable is expressed in terms of a period relating to the duty cycle, for example a step that defines the duration of time during which the duty cycle increases by a predefined amount, and/or a step that defines the duration of time during which the duty cycle decreases by a predefined amount. In embodiments with other types of control signals 170 (for example dependent on voltage level and/or current level) and/or where the change in the value of the variable relating to fan speed is expressed differently, similar methods and systems to those described below can be used mutatis mutandis.

In some embodiments where nonzero changes to variables are expressed as steps, there is a required relationship among different acceleration steps (and similarly among different deceleration steps). For example, in one of these embodiments, steps may be linear in the time domain. As another example, steps may be multiples of other steps. In other embodiments with steps, there is no required relationship among acceleration steps and/or among deceleration steps. Depending on the embodiment, the steps may be stored and retrieved from a table, for example from storage 224, or calculated by using a table or other function.

As a non-limiting example, an adaptable algorithm is now presented for adjusting the fan speed, according to an embodiment of the invention. Some data on the algorithm is presented in table 1 below.

TABLE 1
Algorithm Parameters by Range

| | | | Adjustable | |
|---|---|---|---|---|
| | Slow Down | Fixed | Acceleration | Acceleration |
| | Range | Range | Range | Range |
| Rising | Rising | Fixed | Rising Temperature | Rising |
| Temperature | Temperature Slow | Fan | Acceleration Step | Temperature |
| | Down Step | Speed | (RT_ACC_STEP) | Acceleration Step |
| | (RT_SD_STEP) | | | (RT_ACC_STEP) |
| Falling | Falling | Fixed | Fixed Fan Speed | Falling |
| Temperature | Temperature Slow | Fan | | Temperature |
| | Down Step | Speed | | Acceleration Step |
| | (FT_SD_STEP) | | | (FT_ACC_STEP) |

In the embodiment illustrated by table 1, temperature is divided into four temperature ranges, whose boundaries will be discussed further below. Table 1 is also divided by temperature direction. The change in the value of the variable relating to fan speed, depends on the temperature range in which the temperature determined in stage 302 falls into and/or the direction of that determined temperature (compared to the temperature determined in the previous execution round of stage 302). In this embodiment, the values of four steps, namely Rising Temperature Slow Down Step (RT_SD_STEP), Falling Temperature Slow Down Step (FT_SD_STEP), Rising Temperature Acceleration Step (RT_ACC_STEP), and Falling Temperature Acceleration Step (FT_ACC_STEP) define the changes in the value of the variable relating to fan speed.

The number of different temperature zones and associated steps is not limited by the invention and depending on the embodiments, more or less temperature zones and/or steps may be used than those described with reference to table 1.

In the described embodiment, there is no required relationship between the values of the acceleration steps, (RT_ACC_STEP, FT_ACC_STEP) and the values of the deceleration steps, (RT_SD_STEP, FT_SD_STEP) and therefore the changes in fan speed when accelerating and decelerating also have no required relationship. In other embodiments there may a relationship.

In the described embodiment of the algorithm, the parameters RT_SD_STEP, FT_SD_STEP, RT_ACC_STEP, and FT_ACC_STEP set the periods of time over which the fan duty cycle changes by a certain amount and therefore the higher the step value, the longer the duration of the step (i.e. smaller acceleration or deceleration). However as mentioned above in other embodiments the steps can set the changes of the duty cycle during a fixed period of time, and in these embodiments the higher the step value, the larger the acceleration or deceleration; in still other embodiments, the steps can control factors other than duty cycle. In these other embodiments, similar algorithms to those described below can be used, mutatis mutandis.

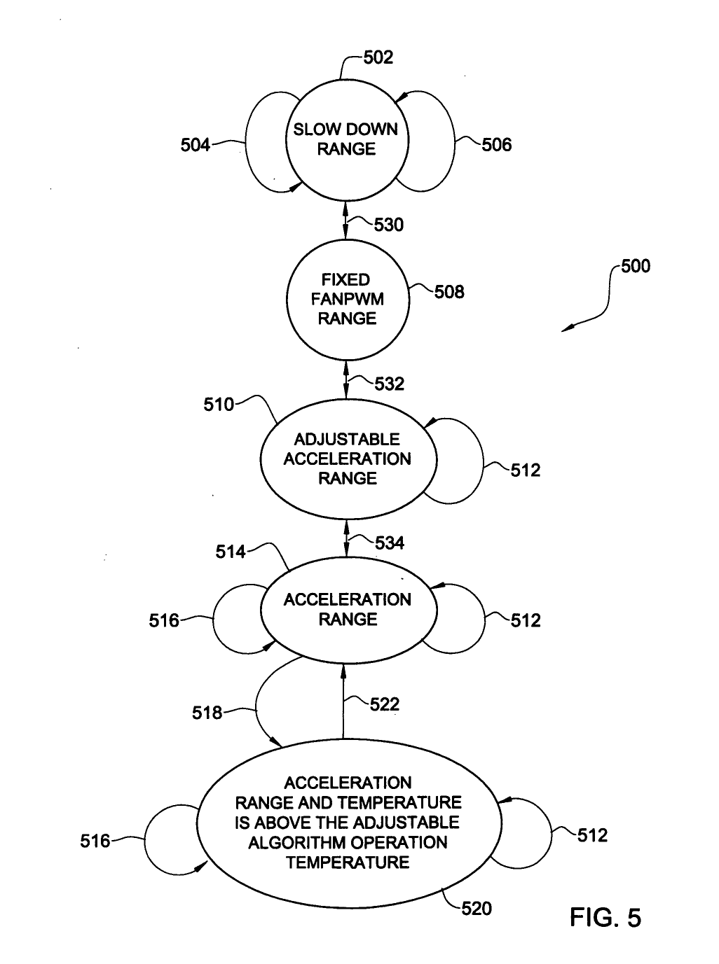

FIG. 5 is a bubble diagram of the adaptable algorithm for table 1, according to an embodiment of the present invention. In the described embodiment, there are four temperature ranges for which there are corresponding predetermined fan speed changes. These temperature ranges are represented by bubbles 502, 508, 510, and 514/520. In the temperature range represented by bubble 520, adaptation of algorithm parameters occurs because the temperature has reached and/or surpassed a predetermined temperature level. The half circles 504 and 516 on the bubbles pointing downwards represent decreasing temperature, whereas the half circles 506 and 512 on the bubbles pointing upwards represent increasing temperature. The straight arrows 522, 530, 532, and 534 between bubbles represent transitions between temperature ranges without affecting algorithm parameters, whereas the half circle 518 between bubbles represents a transition between temperature ranges which may affect algorithm parameters (in an embodiment with adaptive parameters).

In embodiments of the invention where parameter storage 224 includes configuration registers, the values for the boundaries which bound slow down range 502, fixed FANPWM range 508, adjustable acceleration range 510, acceleration range 514 and acceleration range with temperature above a predetermined temperature 520 may be retrieved from parameter storage 224 and/or calculated based on parameters retrieved from parameter storage 224. In some of these embodiments, the number of parameters required to determine the bounds of ranges 502, 508, 510, 514, and 520 may be minimized. For example, in one embodiment, the upper limit of slow down range 502 and the lower limit of fixed FANPWM range 508 are set by the same parameter stored in parameter storage 224. As another example, in one embodiment the addition of the same parameter which sets the lower limit of fixed FANPWM range 508 with a second parameter which specifies the temperature range for both fixed FANPWM range 508 and adjustable acceleration range 510 provides the lower limit of acceleration range 514. As another example in one embodiment, the lower limit of adjustable acceleration range 514 may be calculated by subtracting a parameter representing the adjustable acceleration range (“adjustable acceleration range parameter”) from the calculated lower limit of acceleration range 514. As another example, the lower limit for range 520 (“adjustable algorithm operation temperature”) may be calculated based on a temperature considered to be the hottest permissible (“absolute limit parameter”) for operating the system. For example in one embodiment the adjustable algorithm operation temperature may be calculated as 3 to 5 degrees Celsius below the absolute limit.

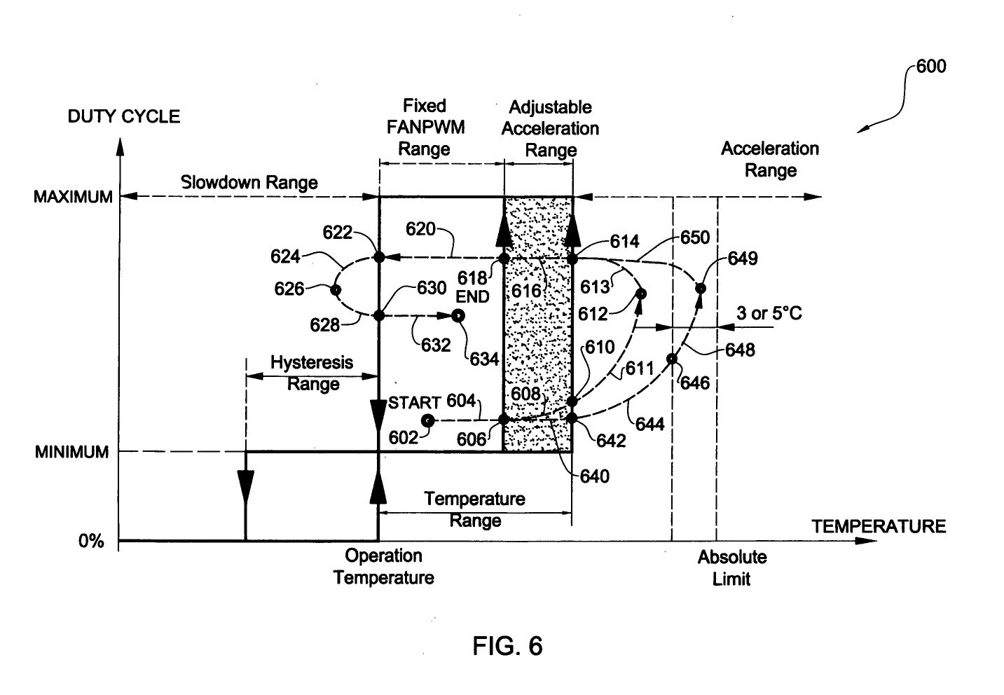

FIG. 5 will be elaborated upon in conjunction with a description of FIG. 6, where FIG. 6 illustrates two examples of the algorithm over time on a graph of duty cycle versus temperature, according to an embodiment of the present invention.

In the first example, the temperature range is assumed to be initially within fixed FANPWM range 508, at start point 602. The initial FANPWM duty cycle can be determined for example in accordance with the last duty cycle (for example the duty cycle or a function thereof may have been stored in parameter storage 224, for example in a configuration register in parameter storage 224). In another embodiment, the initial FANPWM duty cycle may be the minimum duty cycle whose value is configurable. The temperature continues to heat up during temperature range 604 but because the temperature remains in fixed FANPWM range 508, the fan duty cycle is kept constant. At time point 606, the temperature transitions (transition straight arrow 532) into adjustable acceleration range 510. During period 608, the fan accelerates in accordance with the rising temperature acceleration step (RT_ACC_STEP) parameter (half circle 512 on adjustable acceleration range 510). For example, RT_ACC_STEP may for example set a period of time over which the fan duty cycle increases by a predefined amount. RT_ACC_STEP may be retrieved and/or calculated depending on the embodiment. For example, assuming embodiments where parameter storage module includes configuration registers, during period 608 RT_ACC_STEP may be retrieved from the register by TZP 222 in one of these embodiments or in another of these embodiments one or more other parameters may be retrieved by TZP 222, with TZP 222 calculating RT_ACC_STEP using the retrieved parameter(s), for example according to a predefined formula. For example, TZP 222 may continuously calculate over the period of time defined by RT_ACC_STEP the new duty cycle by increasing the previous duty cycle by the predefined amount over the predefined period of time. TZP 222 can therefore continuously provide to FSC 226 the new duty cycle, so that FSC 226 can output PWM signals 170 with the new duty cycle.

At point 610, the temperature enters into acceleration range 514 (transition straight arrow 534). During period 611, RT_ACC_STEP (half circle 512 on acceleration range 514) continues to be applied (i.e. the fan accelerates), until the temperature reaches an approximate high point at time point 612 where there is a balance between heating up of the electronic system and the cooling off of the electronic system by fan 150. Thereafter the temperature starts to reduce during period 613. During period 613, the fan accelerates according to the rate set by the falling temperature acceleration step (FT_ACC_STEP) parameter (half circle 516 on acceleration range 514). For example, FT_ACC_STEP may set a period of time over which the fan duty cycle increases by a predefined amount. FT_ACC_STEP may be retrieved and/or calculated depending on the embodiment. For example, assuming embodiments where parameter storage module includes configuration registers, during period 613, FT_ACC_STEP may be retrieved from the register by TZP 222 in one of these embodiments, or in another of these embodiments one or more other parameters may be retrieved by TZP 222, with TZP 222 calculating FT_ACC_STEP for example using the retrieved parameter(s) according to a predefined formula. For example, TZP 222 may continuously calculate over the period of time defined by FT_ACC_STEP the new duty cycle by increasing the previous duty cycle by the predefined amount over the predefined period of time. TZP 222 can therefore continuously provide to FSC 226 the new duty cycle, so that FSC 226 can output PWM signals 170 with the new duty cycle.

In one embodiment, the parameter FT_ACC_STEP which sets the period of time over which the fan duty cycle increases by a predefined amount during temperature falls in acceleration range 514, is equal to or larger than the parameter RT_ACC_STEP which sets the period of time over which the fan duty cycle increases by a predefined amount during temperature rises. Therefore, in this embodiment the speed may in some cases be increased more gradually during a temperature fall (where there is less risk of overheating) than during a temperature rise, leading in some instances to less noise overall.

In another embodiment, for time period 613 (i.e. during falling temperature within acceleration range 514), there is either no change in the fan duty cycle or a small decrease in the fan duty cycle. In other words, in this other embodiment, FT_ACC_STEP either causes no change in the fan duty cycle or sets a period of time over which the fan duty cycle decreases by a small predefined amount. It is assumed in any case, that the temperature will drop during period 613.

The temperature reduces sufficiently at time point 614 to re-enter adjustable acceleration range 510 (transition straight arrow 534). As the temperature continues to decrease during period 616, the speed of the fan is maintained. At time point 618, the temperature has reduced sufficiently to re-enter fixed FANPWM range 508 (transition straight arrow 532). The speed of the fan continues to be maintained during period 620 until time point 622 when the temperature enters slowdown range 502 (transition straight arrow 530). During period 624, as the temperature falls, the fan decelerates in accordance with the falling temperature slow down step (FT_SD_STEP) parameter (half circle 504 on slow down range 502). For example, FT_SD_STEP may for example set a period of time over which the fan duty cycle decreases by a predefined amount. FT_SD_STEP may be retrieved and/or calculated depending on the embodiment. For example, assuming embodiments where parameter storage module includes configuration registers, during period 624 FT_SD_STEP may be retrieved from the register by TZP 222 in one of these embodiments or in another of these embodiments one or more other parameters may be retrieved by TZP 222, with TZP 222 calculating FT_SD_STEP using the retrieved parameter(s), for example according to a predefined formula. For example, TZP 222 may continuously calculate over the period of time defined by FT_SD_STEP the new duty cycle by decreasing the previous duty cycle by the predefined amount over the predefined period of time. TZP 222 can therefore continuously provide to FSC 226 the new duty cycle, so that FSC 226 can output PWM signals 170 with the new duty cycle.

At point 626 the temperature reaches an approximate low point where there is a balance between heating up of the electronic system and the cooling off of the electronic system by fan 150 and thereafter the temperature starts to increase. During period 628 while the temperature is rising, the fan decelerates according to the rate set by the rising temperature slow down step (RT_SD_STEP) parameter (half circle 506 on slow down range 502). For example, RT_SD_STEP may for example set a period of time over which the fan duty cycle decreases by a predefined amount. RT_SD_STEP may be retrieved and/or calculated depending on the embodiment. For example, assuming embodiments where parameter storage module includes configuration registers, during period 628 RT_SD_STEP may be retrieved from the register by TZP 222 in one of these embodiments or in another of these embodiments one or more other parameters may be retrieved by TZP 222, with TZP 222 calculating RT_SD_STEP using the retrieved parameter(s), for example according to a predefined formula. For example, TZP 222 may continuously calculate over the period of time defined by RT_SD_STEP the new duty cycle by decreasing the previous duty cycle by the predefined amount over the predefined period of time. TZP 222 can therefore continuously provide to FSC 226 the new duty cycle, so that FSC 226 can output PWM signals 170 with the new duty cycle.

In one embodiment the parameter RT_SD_STEP which sets the period of time over which the fan duty cycle decreases by a predefined amount during rising temperature in slow down range 502, is equal to or larger than the parameter FT_SD_STEP which sets the period of time over which the fan duty cycle decreases by a predefined amount during falling temperature in slow down range 502 in order to prevent overheating of the electronic system while preserving low fan speed. As is known to the reader, if a fan slows down too quickly, the temperature may increase too rapidly causing the temperature to enter into adjustable acceleration range 510 and possibly start oscillating. Slow fan deceleration may in some cases be required to prevent oscillation.

At time point 630, the temperature re-enters fixed range 508 (straight arrow 530) and the fan speed is maintained during period 632 as the temperature rises, for example the duty cycle may be kept during period 632 at the same duty cycle as at time point 630. At point 634 the example ends.

In some embodiments of the algorithm, a minimum duty cycle parameter can be retrieved, for example from parameter storage 224 or calculated. In one of these embodiments, if the temperature is falling and crosses into slow down range 502 from fixed range 508 (transition straight arrow 530), FSC 226 decreases the duty cycle of PWM signals 170 by the predefined amount over the period of time based on FT_SD_STEP. A hysteresis value (aka hysteresis temperature range) can be defined for example as a number of degrees below the lower bound of fixed range 508. The hysteresis value may be retrieved for example from parameter storage 224 or calculated. In one embodiment, if the minimum duty cycle function is enabled and the temperature is under the defined hysteresis range then if the minimum duty cycle is reached, fan(s) 150 will be immediately stopped.

The value of the minimum duty cycle which can not be passed (i.e. decelerating cannot lead to a lower duty cycle than the minimum duty cycle if enabled) can vary depending on the embodiment. In one of these embodiments the minimum duty cycle is 0% (i.e. off). In another of these embodiments, the minimum duty cycle is larger than 0%. For example, in one of these embodiments the minimum duty cycle is 50%.

In some embodiments of the algorithm, there is a hysteresis temperature range, for example for 1 degree Celsius, during the transition from rising temperature to falling temperature and vice versa (for example time point 612 and/or 626). In some of these embodiments, within the hysteresis range the PWM duty cycle continues to be affected by the previous step. For example even if the temperature falls from point 612, the RT_ACC_STEP will continue to be used until the hysteresis range is passed (and only then the FT_ACC_STEP will be used)

In one embodiment of the invention, there is no required relationship between the length of the period of time defined by RT_SD_STEP. FT_SD_STEP, RT_ACC_STEP, or FT_ACC_STEP and the period between two sequential temperature measurements. In this embodiment, the total change in duty cycle defined by the RT_SD_STEP, FT_SD_STEP. RT_ACC_STEP, or FT_ACC_STEP does not necessarily have to be achieved prior to the next temperature measurement. In another embodiment, there may be a required relationship, for example the length of the period of time may be required to be at most equal to the period between two sequential temperature measurements.

Another example of the algorithm is now presented with reference to FIGS. 5 and 6. In this example, at time point 606, it is assumed that the period of time over which the fan duty cycle increases by a predefined amount in accordance with RT_ACC_STEP is larger than for the first example, and therefore the fan speed accelerates more slowly during period 640 than in the previous example (period 608). The entry into acceleration range 514 at time point 642 is thus at a lower duty cycle than for the previous example (time point 610). During period 644, the duty cycle continues to increase by a predefined amount in accordance with RT_ACC_STEP but the increases are not sufficient to prevent the temperature from reaching the adjustable algorithm operation temperature at time point 646 and entering temperature range 520 (transition 518). In one embodiment, because the adjustable algorithm operation temperature has been reached, one or more parameters impacting on the correspondence between temperature and the change in value of a variable relating to fan speed may be adjusted. For example, in one embodiment the period of time over which the fan duty cycle increases by a predefined amount in accordance with RT_ACC_STEP is decreased so that there is faster acceleration during period 648 (within temperature range 520 or whenever the temperature is above fixed range 508 and the temperature is rising) than would have been otherwise. In another embodiment the adjustable acceleration range parameter is also or instead increased, causing the lower limit of the adjustable acceleration range to be moved to a lower temperature and therefore the RT_ACC_STEP to be applicable at a lower rising temperature. It should be evident that by adjusting the lower limit, the acceleration is applied for any rising temperature which used to be in the fixed range 508 but is now in adjustable acceleration range 512.

For example in one embodiment, there is a stored or calculated value which sets the amount that is subtracted from the RT_ACC_STEP whenever the temperature reaches the adjustable algorithm operation temperature, thereby reducing the period of time in which the duty cycle increases by a predefined amount by that value. In one embodiment the value may be zero (i.e. not adjustable) or higher. In one embodiment, there a limited number of choices to which the value can equal. In one embodiment, the value subtracted is in accordance with a table and/or other function.

For example in one embodiment, there is a stored or calculated value which sets the amount which is added to the adjustable acceleration range whenever the temperature reaches the adjustable algorithm operation temperature, thereby causing the lower limit of the adjustable acceleration range to be moved to a lower temperature. In one embodiment the value may be zero (i.e. not adjustable) or higher. In one embodiment, there a limited number of choices to which the value can equal. In one embodiment, the value added is in accordance with a table and/or other function.

In one embodiment, the (adjustable) parameter(s) are adjusted once each time the adjustable algorithm operation temperature is reached and the newly adjusted parameter(s) remain at the adjusted values unless the adjustable algorithm operation temperature is again reached from below and/or the CPU changes the values of the parameter(s). In other embodiments, the parameter(s) may be adjusted more than once when above the adjustable algorithm operation temperature, for example based on the amount of time the temperature is above the adjustable algorithm operation temperature, for example based on temperature direction, change in temperature and/or rate of change of temperature, and/or for example if the temperature reaches a second higher predefined adjustable algorithm operation temperature.

There is no limitation on how many parameters are adjusted, which parameters are adjusted, how the parameters are adjusted, how many times the parameters are adjusted etc. and any of these can vary depending on the embodiment.

For example, in an embodiment where the change in the value of the variable is expressed as the change in the duty cycle in a fixed period of time or the period in which the duty cycle changes by a predefined amount, examples of adjustable parameters include inter-alia one or more of the following: change in duty cycle in one or more of ranges 502, 510, 514, and 520; period during which duty cycle changes in one or more of ranges 502, 510, 514, and 520, the upper and/or lower bounds of one or more of ranges 502, 508, 510, 514, and 520, predetermined level(s) and/or range(s) where adaptation occurs, predetermined relationship(s) to be checked, the impact of time when predetermined relationship(s) hold on the adaptability, the correspondence between change in duty cycle (and/or period during which duty cycle changes) with temperature (including one or more of: temperature, temperature direction, temperature change, temperature range, rate of change in temperature, time temperature is at the same level or within same range, etc), and correspondence between parameters and ambient temperature.

At time point 649, the temperature reaches an approximate high point, and begins to fall. During period 650, the duty cycle of PWM signals 170 is increased by the predefined amount over the period of time based on the FT_ACC_STEP until time point 614 is reached and the example continues as in the first example.

If instead of reaching an approximate high point at time point 649, the temperature continued to rise until it reached the absolute limit temperature, then in some embodiments the duty cycle would be forced to the maximum duty cycle. In one of these embodiments, once the temperature returns below the absolute limit, the maximum duty cycle is maintained for a predefined temperature range (for example as defined by a hysteresis value which indicates a number of degrees below the absolute limit).

In some embodiments of the invention, there is a maximum duty cycle (stored in parameter storage 224 or calculated) which cannot be passed (In other words accelerating cannot lead to a higher duty cycle than the maximum duty cycle). In one of these embodiments, the maximum duty cycle is 100%. In other embodiments, the maximum duty cycle is less than 100%.

The description above referred to approximate high point (612, 649) and approximate low point 626 because in some embodiments, the point where the temperature is assumed to change direction (i.e. approximate high point or approximate low point) may vary slightly from the actual high point or low point. For example in one of these embodiments, for falling to rising temperature, the assumed temperature low point is a certain amount higher than the actual low point temperature, and for rising to falling temperature, the assumed temperature high point is a certain amount lower than the actual high point temperature.

As mentioned above, it was assumed above that there only one temperature measurement module 110 was used. However, it is possible that system 100 includes more than one temperature measurement modules 110, for example with each monitoring a different temperature zone and/or channel. In one embodiment, each measurement module 110 is associated with a separate fan driver 140 and fan 150. For example each associated measurement module 110, fan driver 140 and fan 150 may share the same zone. In this embodiment, the change in the value of the variable relating to fan speed for each fan 150 is determined independently based on the temperature reading 160 of the associated measurement module 110 in accordance with the methods and systems described above.

In other embodiments, each fan 150 is associated with a plurality of temperature measurement modules 110, for example with each monitoring a different temperature zone and/or channel. Depending on the embodiment, for each two fans 150, there may be no overlap, some overlap or total overlap between the temperature measurement modules 110 associated with each of the two fans 150. In some of these other embodiments, for each fan 150, temperature readings 160 from only one measurement module 110 associated with that particular fan 150 are used to determine the change in the variable relating to fan speed for that particular fan 150, in accordance with the methods and systems described above. In one of these other embodiments, the measurement module 110 whose temperature reading 160 is used may vary, for example with a reading 160 from each measurement module 110 used in turn.

In another of these other embodiments, the highest temperature reading 160 received from all temperature measurement modules 110 associated with a particular fan 150 is used to determine the fan speed changes in accordance with the methods and systems described above.

In one embodiment of the invention, each fan 150 is associated with a plurality of temperature measurement modules 110, for example with each monitoring a different temperature zone and/or channel. Depending on the embodiment, for each two fans 150, there may be no overlap, some overlap or total overlap between the temperature measurement modules 110 associated with each of the two fans 150. In this embodiment, where the temperature readings from the temperature measurement modules 110 associated with a particular fan(s) may in some cases correspond to a plurality of different changes in the value of the variable relating to fan speed, the temperature reading which results in the highest speed for the particular fan(s) 150 is in effect used.

FIG. 7 is a flowchart of a method 700 of controlling the fan speed with multiple temperature measurements, according to this embodiment of the current invention. In other embodiments, method 700 may include fewer, more or different stages than those illustrated in FIG. 7, the order of stages may differ from the order in FIG. 7, and/or one or more stages may be executed simultaneously. In FIG. 7, it is assumed for ease of description that there are N measurement modules 110, providing N temperature readings 160, that are associated with a particular fan or fans 150 and that FSC 226 outputs a PWM signal. For N times, i.e. once for each measurement module 110, stages 302, 304 and 702 are executed by TZP 222 to determine the change in the value of the variable relating to fan speed which is associated with each determined temperature and therefore the resultant PWM duty cycle. The iteration variable “m” is used in FIG. 7 for the sake of clarity. In stage 704 the highest PWM duty cycle is selected by FSC 226 and reflected in PWM signals 170 which are used to control the associated fan or fans 150.

It should be understood that in the embodiment of FIG. 7, what is important is that the temperature which would result in the highest fan speed is used to control fan(s) 150. Therefore, in another embodiment, in stage 702, instead of or in addition to determining the corresponding duty cycle, the value of another variable relating to fan speed (for example voltage level and/or current level) may be calculated for each temperature measurement and in this other embodiment in stage 704, FSC 226 selects the highest value of the variable (and/or the value which would lead to the highest fan speed) and reflects the selection in control signal 170.

Optionally, assuming an adaptable algorithm, stage 404 is next executed where the temperature corresponding to the selected highest PWM duty cycle (to the selected highest other variable value and/or to selected the variable value leading to the highest fan speed) is compared with one or more predetermined levels/predetermined ranges by TZP 222 for one or more predetermined relationships, and if there exists at least one of the predetermined relationships between the corresponding temperature and the predetermined level(s)/range(s) then in stage 406 one or more parameters are adjusted using the methods and systems described above.

In another embodiment assuming an adaptable algorithm, stage 404 is executed after stage 302 for each temperature measurement reading from each measurement module 110 (rather than only for the corresponding temperature). If there is at least one predetermined relationship between the temperature and the predetermined level(s)/range(s) for any one or more of the N temperature measurement readings, then in stage 406 one or more parameters are adjusted using the methods and systems described above.

In some embodiments, method 700 may be simultaneously executed for each fan 150 (or fans 150) associated with a different group of measurement modules 110. Depending on the embodiment, N may be the same or may vary for different groups of measurement modules 110.

In another aspect of the invention, TMFC 120 is distinct from the CPU of the electronic system whose temperature is being attempted to be controlled. In this other aspect of the invention, the one or more modes in which TMFC 120 may operate includes a mode where temperatures may instead or also correspond directly to the value of a variable relating to fan speed. In this other aspect, TMFC 120 is configured to adjust parameters impacting on the correspondence between temperatures and the values of the variable relating to fan speed. Therefore in this other aspect TMFC 120 is made up of any combination of software, hardware and or firmware which allow TMFC 120 to provide the functionality of adjustment of parameters impacting on the correspondence between temperature and the value of the variable relating to fan speed, in addition to or instead of the functionality described above.

Refer to FIG. 9 which illustrates an algorithm where the duty cycle is proportional to the measured temperature, according to an embodiment of this aspect of the invention. FIG. 9 will be described in conjunction with FIG. 10 which illustrated a method 1000 in accordance with an embodiment of this aspect of the invention.

When discussing here and below parameters affecting the correspondence between temperature and the variable relating to fan speed, it should be understood that the discussed correspondence includes any type of correspondence with temperature, including correspondence with one or more of the following inter-alia: temperature, temperature range including temperature, temperature direction, change in temperature, rate of change in temperature, time temperature is at the same level or within same range etc. In other embodiments, method 1000 may include fewer, more or different stages than those illustrated in FIG. 10, the order of stages may differ from the order in FIG. 10, and/or one or more stages may be executed simultaneously.

In stage 1002, the temperature(s) is determined by TZP 222. For example TZP 222 may receive a temperature measurement from temperature measurement module 110 as discussed above with reference to stages 402 and 302. As another example, if more than one temperature measurement module area associated with a particular fan or fans 150, in one embodiment, all of the received temperatures may be used in stage 1004. As another example, if more than one temperature measurement module 110 are associated with a particular fan or fans 150, in one embodiment the temperature reading corresponding to the value of the variable that results in the highest fan speed (for example, highest PWM duty cycle, highest voltage level, highest current level) is used in stage 1002. Continuing with this example, if the variable is the duty cycle then the temperature reading which is associated with the highest duty cycle is selected. In other embodiments where more than one temperature measurement module 110 are associated with a particular fan or fans 150, other ways of determining a temperature reading in stage 1002 can be used; for example the highest temperature reading, or the temperature reading from a particular measurement module 110, etc can be used.

In stage 1004, it is determined whether the temperature(s) has a predetermined relationship(s) with one or more predetermined temperature levels and/or one or more predetermined temperature ranges. For example in one embodiment, checking whether the temperature(s) has one or more predetermined relationship with the predetermined temperature level(s)/range(s) and acting accordingly, improves the temperature control provided by system 100. If more than one temperature is checked (for example from different measurement modules 110 associated with a particular fan or fans 150), then stage 1004 can be repeated for each temperature reading. For simplicity of description, it is assumed that there is one predetermined relationship and one predetermined temperature level which should be checked. Depending on the embodiment, the determination in stage 1004 may be whether the temperature is at a predetermined level, at or below a predetermined level, at or above a predetermined level, below a predetermined level, above a predetermined level, or having any predetermined relationship with a predetermined temperature level. The predetermined temperature level may be any appropriate level and the predetermined relationship may be any appropriate relationship. If the determination is that the temperature (for example the measured temperature, the corresponding temperature, or at least one of the measured temperatures) has a predetermined relationship with a predetermined level, then in stage 1006, one or more parameters affecting the correspondence between temperature and the value of the variable relating to fan speed are adjusted. With or without adjustment, method 1000 repeats as long as temperature monitoring is desirable (for example in one embodiment method 1000 repeats as long as the electronic system whose temperature is controlled by system 100 is on).

For example in one embodiment, the predetermined level is based on an “absolute limit” temperature which is considered the hottest for the electronic system whose temperature is being controlled. The decision of what is the “hottest” permissible may vary depending on the electronic system and/or other factors. Continuing with this example, the predetermined level may be a certain number of degrees, say 3 degrees Celsius to 5 degrees Celsius below the absolute limit. Still continuing with the example, in stage 1004 it can be checked whether the temperature is at or above the predetermined level and if yes, one or more parameters may be adjusted in stage 1006, for example so that the temperature is less likely to continue to rise high enough to reach the absolute limit and/or so that in the future the temperature is less likely to reach the predetermined level. It should be evident to the reader, that in another embodiment the same limitation could be checked defining the absolute limit as the predetermined level and the predetermined relationship as “at or above 3 to 5 degrees Celsius below the predetermined level.

In some embodiments, one or more parameters impacting on the correspondence between temperature and the value of the variable relating to fan speed can be adjusted, making higher temperatures more likely. For example, a table of minimum and/or maximum values for one more parameters corresponding to ambient temperatures can be set. As another example a table recording the historical correspondence between minimum and/or maximum values of one or more parameters and ambient temperature may be maintained. This historical table can be updated in some embodiments on the fly. In either of these examples, in stage 1004, if the temperature has not reached a predetermined level during a predetermined period of time, and the electronic system is on (i.e. not off or sleeping), then one or more parameters can be adjusted in stage 1006, so that the temperature is more likely to reach the predetermined level. In one embodiment, the predetermined level is based on the “absolute limit” temperature, for example a certain number of degrees, say 3 degrees Celsius to 5 degrees Celsius below the absolute limit. In one embodiment, the adjustment takes into account the set and/or historical correspondence with the ambient temperature. For example, assuming a certain ambient temperature value, the speed may be allowed to drop a certain amount lower than the set and/or historical value of the speed level achieved when the temperature exceeded the predetermined level and the ambient temperature equaled that certain value. By taking the ambient temperature into account, this embodiment prevents the ambient temperature from exercising an inordinate influence on the fan speed.

In another embodiment, there may be one or more temperature ranges (instead of or in addition to levels), and if the temperature (for example, the measured temperature, corresponding temperature or one of the measured temperatures) is determined to be in these one or more ranges (in stage 1004), then one or more parameters impacting on the correspondence between temperature and values of the variable relating to fan speed are adjusted in stage 1006. For example, assuming a plurality of temperature ranges, in one embodiment, there is an adaptation of one or more parameters for each range. If there are different ranges, in some embodiments there is no required relationship between which parameters are adapted and/or how the parameters are adapted for each range in stage 1006. For example in one of these embodiments, there may be two temperature ranges where the corresponding value of the variable relating to fan speed is adjusted to become higher. Continuing with the example, if the determined temperature reaches the lower temperature range, there may be a first adaptation where the value becomes higher and if the determined temperature reaches a higher temperature range, there may be a second additional adaptation where the value becomes higher. Similarly there may be a plurality of temperature ranges where the corresponding value of the variable relating to fan speed is adjusted to become lower.

In some embodiments, the amount of time which the temperature has a predetermined relationship(s) with predefined level(s)/range(s) impacts on the adaptation in stage 1006 of one or more parameters affecting the correspondence between temperature and values of the variable relating to fan speed. The impact can be for example on which parameter(s) are adapted and/or on how the parameter(s) are adapted. For example in some of these embodiments, the value of the variable relating to fan speed may be defined so that the longer the temperature has at least one predetermined relationship with a predefined level(s)/range(s), the higher the speed corresponding to at least one temperature. Continuing with the example, in one of these embodiments for each consecutive sampling (i.e. repetition of stage 1002) where the received temperature, corresponding temperature or one of the received temperatures, is determined in stage 1004 to have a predefined relationship with a predefined level(s)/range(s), the value is redefined in stage 1006, causing, for example, an increased speed corresponding to at least one temperature. Similarly the value of the variable relating to fan speed may be defined so that the longer the temperature has a predetermined relationship with predefined level(s)/temperature range(s), the lower the acceleration (or the higher the deceleration) corresponding to at least one temperature.

In some embodiments, the change in determined temperature, for example from the temperature determined in the previous execution round of stage 1002 may be calculated by TZP 222 and may in some cases affect the adaptation in stage 1006 of one or more parameters which impact on the correspondence between temperature and the values of the variable relating to fan speed. For example in one of these embodiments, which parameter(s) are adapted and/or how the parameters are adapted may depend on the change in temperature.

In some embodiments, the temperature direction, for example from the temperature determined in the previous execution round of stage 1002 may be calculated by TZP 222 and may in some cases affect the adaptation in stage 1006 of one or more parameters which impact on the correspondence between temperature and the values of the variable relating to fan speed. For example in one of these embodiments, which parameter(s) are adapted and/or how the parameters are adapted may depend on the temperature direction.

In some embodiments, the temperature deviation may be calculated by TZP 222 and may in some cases affect the adaptation in stage 1006 of one or more parameters which impact on the correspondence between temperature and the values of the variable relating to fan speed. For example in one of these embodiments, which parameter(s) are adapted and/or how the parameters are adapted may depend on the temperature deviation.

In some embodiments, which of a plurality of predetermined relationships holds between said determined temperature and predefined level(s)/range(s) impacts on the adaptation in stage 1006 of one or more parameters affecting the correspondence between temperature and the values of the variable relating to fan speed.

The amount of adjustment of any parameters in stage 1006 may be determined in any appropriate way. For example, the amount of adjustment may be stored and retrieved from parameter storage 224, calculated using a table and/or another function, etc.

In one embodiment of this aspect of the invention the adjustable parameters include one or more of the following: the low limit of the proportional range 902, the high limit of the proportional range 904, the maximum variable value (for example duty cycle) 906, the minimum duty cycle 908, the slope of the proportional range, value of a variable (for example duty cycle) in a temperature range, bound of a temperature range, predetermined level where adaptation occurs, predetermined range where adaptation occurs, predetermined relationship to be checked, impact of time duration during which a predetermined relationship holds on adaptability, one or more variable values (for example one or more duty cycles) corresponding to one or more temperatures, the correspondence between the value of the variable relating to fan speed with temperature (including one or more of: temperature, temperature direction, temperature change, temperature range, rate of change in temperature, time temperature is at the same level or within same range, etc), and correspondence between parameters and ambient temperature.

In another aspect of the invention, there is a plurality of temperature measurement modules 110 associated with a particular fan or fans 150. In this aspect the values of a variable relating to fan speed (for example the duty cycle, voltage level, current level) corresponding to each of the plurality of temperature readings 160 may be determined in any fashion, including inter-alia using a correspondence between the change in the value of the variable (for example change in duty cycle, change in voltage level, change in current level or a function thereof) and temperature (or a function thereof), or using a correspondence between the value of the variable (for example duty cycle, voltage level, current level or a function thereof) and temperature (or a function thereof), etc. The value of the variable relating to fan speed (for example duty cycle, voltage level, current level) is calculated for each temperature reading 160 and the variable value which results in the highest fan speed (for example the highest duty cycle, voltage level, current level) out of those calculated is selected. FSC 228 outputs control signals 170 based on the selected variable value (for example PWM signals with the selected highest duty cycle, voltage level, current level).

It will also be understood that some or all of the system according to the invention may be a suitably programmed computer. Likewise, the invention contemplates a computer program being readable by a computer for executing a method of the invention. The invention further contemplates a machine-readable memory tangibly embodying a program of instructions executable by the machine for executing a method of the invention.

While the invention has been shown and described with respect to particular embodiments, it is not thus limited. Numerous modifications, changes and improvements within the scope of the invention will now occur to the reader.

1. A method of controlling a speed of a fan for an electronic system comprising:
determining a temperature relating to the electronic system;
determining a change in a value of a variable relating to fan speed which corresponds to said determined temperature; and
if there is a nonzero determined corresponding change in a value of said variable relating to fan speed, causing the speed of a fan to change in accordance with said determined corresponding change.

2. The method of claim 1, further comprising: determining which predetermined temperature range of adjacent temperatures includes said determined temperature, wherein a correspondence between said change in a value of said variable and said determined temperature depends at least partially on which predetermined temperature range of adjacent temperatures includes said determined temperature.

3. The method of claim 1, further comprising: determining a temperature direction from a last previously determined temperature, wherein a correspondence between said change in a value of said variable and said determined temperature depends at least partially on said determined temperature direction.

4. The method of claim 3, wherein said causing causes said speed of the fan to change more if said determined temperature is higher than a last previously determined temperature compared to if said determined temperature is lower than a last previously determined temperature.

5. The method of claim 1, wherein a correspondence between said change in a value of said variable and said determined temperature, depends at least partially on at least one selected from a group comprising: change between said determined temperature and a last previously determined temperature, time duration in which said determined temperature has remained identical or within an identical range, and rate of change in temperature.

6. The method of claim 1, further comprising: if said corresponding change is zero, causing said speed of the fan to be maintained.

7. The method of claim 6, wherein said determined temperature is included in a range of adjacent temperatures associated with maintained fan speed.

8. The method of claim 1, further comprising: continuously calculating a new value of said variable or a function thereof to incorporate said corresponding change in a value of said variable over a period of time.

9. The method of claim 8, wherein said corresponding change in said value of said variable is expressed as a change in a duty cycle or a function thereof over a period of time, further comprising: continuously calculating a new duty cycle to incorporate said corresponding change over said period of time.

10. The method of claim 8, wherein said calculated new value or a function thereof is a voltage level or current level.

11. The method of claim 1, further comprising: checking if said determined temperature has a predetermined relationship with a predetermined temperature level or range and if said determined temperature has a predetermined relationship, adjusting a parameter impacting on a correspondence between temperature and change in a value of a variable relating to fan speed.

12. The method of claim 1, wherein said determining a temperature includes:
determining a plurality of temperatures relating to the electronic system which are associated with the fan; and
wherein said determining a change includes:
for each of said plurality of temperatures, determining a corresponding change in a value of a variable relating to a fan speed and calculating a value of said variable relating to fan speed or a function thereof based on said corresponding change; and
wherein said causing includes:
selecting a value of said variable or a function thereof which would lead to a highest fan speed out of said calculated values and outputting a control signal which reflects said selection.

13. A method of controlling a speed of a fan for an electronic system, comprising:
determining a temperature relating to the electronic system;
checking whether said temperature has a predetermined relationship with a predetermined temperature level or range; and
if said temperature has a predetermined relationship, adjusting at least one parameter which affects a correspondence between temperature and change in a value of a variable relating to fan speed.

14. The method of claim 13, wherein said adjusting causes a different change in a value of said variable to correspond to said particular temperature than previously.

15. The method of claim 14, wherein said adjusting causes a larger change in a value of said variable to correspond to said particular temperature than previously.

16. The method of claim 14, wherein said adjusting causes a smaller change in a value of said variable to correspond to said particular temperature than previously.

17. The method of claim 13, wherein prior to said adjusting said particular temperature corresponded to a zero change in said value of said variable, and after said adjusting said particular temperature corresponds to a nonzero change in said value of said variable.

18. The method of claim 17, further comprising: dividing temperatures into temperature ranges, wherein said adjusting includes adjusting a bound of at least one of said temperature ranges.

19. The method of claim 13, wherein said adjusting adjusts at least one selected from a group comprising: change in value of a variable relating to fan speed in a temperature range; bound of a temperature range, predetermined level where adaptation occurs, predetermined range where adaptation occurs, predetermined relationship to be checked, impact of time duration during which a predetermined relationship holds on adaptability, correspondence between ambient temperatures and parameters, correspondence between change in value of a variable relating to fan speed with temperature, correspondence between change in value of a variable relating to fan speed and temperature direction, correspondence between change in value of a variable relating to fan speed and temperature change, correspondence between change in value of a variable relating to fan speed and temperature range, correspondence between change in value of a variable relating to fan speed and rate of temperature change, and correspondence between change in the value of the variable relating to fan speed with time temperature is at a same level or range.

20. The method of claim 13 wherein said predetermined level is a function of a highest allowable temperature for the electronic system.

21. The method of claim 13, wherein said adjusting is affected by at least one selected from a group comprising: change in temperature, temperature direction, temperature deviation, duration of time in which said predetermined relationship holds, which of a plurality of predetermined relationships holds between said temperature and said predetermined level or range, with which of a plurality of levels said temperature has a predetermined relationship, and with which of a plurality of ranges said temperature has a predetermined relationship.

22. A method of controlling a speed of a fan in an electronic system, comprising:
determining a temperature relating to the electronic system;
determining a temperature range which includes said determined temperature;
determining a temperature direction;
determining a corresponding change in duty cycle over time, or function thereof, for said determined temperature range and determined temperature direction;
determining a new duty cycle based on said corresponding duty cycle change over time, or a function thereof; and
outputting a PWM signal with said new duty cycle.

23. A method of controlling a speed of a fan in an electronic system, comprising:
determining a plurality of temperatures relating to the electronic system which are associated with the fan;
for each of said plurality of determined temperatures, calculating a value of a variable relating to fan speed or a function thereof corresponding to said each determined temperature;
selecting a value of said variable or a function thereof which would lead to a highest fan speed out of said calculated values; and
outputting a control signal reflecting said selection.

24. The method of claim 23, further comprising:
for each of said plurality of determined temperatures, determining a corresponding change in a value of said variable relating to fan speed;
wherein for each of said plurality of determined temperatures said calculating is based on said corresponding change.

25. The method of claim 23, further comprising:
for each of said plurality of temperatures, determining a corresponding value of said variable relating to a fan speed;
wherein for each of said plurality of determined temperatures said calculating is based on said corresponding value.

26. The method of claim 23, wherein said control signal includes at least one from a group comprising: PWM signal with selected highest duty cycle, selected highest voltage level, selected highest current level, PWM signal with duty cycle which would lead to highest fan speed, voltage level which would led to highest fan speed, and current level which would lead to highest fan speed.

27. The method of claim 23, further comprising: checking whether any of said plurality of temperatures has a predetermined relationship with a predetermined temperature level or range; and if any of said plurality of temperatures has a predetermined relationship, adjusting at least one parameter which affects fan speed.

28. A method of controlling a speed of a fan for an electronic system including a central processing unit, comprising:
determining a temperature relating to said electronic system;
checking whether said temperature has a predetermined relationship with a predetermined temperature level or range; and
if said temperature has a predetermined relationship, adjusting at least one parameter which affects fan speed;
wherein said checking and adjusting occur outside of the central processing unit, and wherein said at least one parameter is selected from a group comprising: slope of a range where a variable relating to fan speed is proportional to temperature, slope of a range where duty cycle is proportional to temperature, maximum value of a variable relating to fan speed, maximum duty cycle, minimum value of a variable relating to fan speed, minimum duty cycle, predetermined level where adaptation occurs, predetermined range where adaptation occurs, predetermined relationship to be checked, impact of time duration during which a predetermined relationship holds on adaptability, correspondence between ambient temperatures and parameters, correspondence between value of a variable relating to fan speed and temperature direction, correspondence between value of a variable relating to fan speed and temperature change, correspondence between value of a variable relating to fan speed and rate of temperature change, and correspondence between value of the variable relating to fan speed with time temperature is at a same level or range.

29. A system for controlling a speed of a fan for an electronic system, comprising:
a temperature monitoring and fan control module, wherein said temperature monitoring and fan control module is configured to receive temperature readings relating to the electronic system, configured to determine changes in the values of at least one variable which correspond to said temperature readings, and configured to generate control signals capable of causing a fan to change or maintain speed in accordance with said determined changes.

30. The system of claim 29, further comprising:
a fan configured to change or maintain speed in accordance with said determined changes; and
a temperature measurement module configured to provide to said temperature monitoring and fan control module temperature readings relating to the electronic system.

31. A system for controlling a speed of a fan for an electronic system, comprising:
a temperature monitoring and fan control module, wherein said temperature monitoring and fan control module is configured to receive temperature readings relating to the electronic system, configured to check whether a received temperature reading has a predetermined relationship with a predetermined temperature level or range; and configured to adjust at least one parameter which affects a correspondence between temperature and change in the value of a variable relating to fan speed, if said received temperature reading has a predetermined relationship.

32. A system for controlling a speed of a fan for an electronic system, comprising:
means for determining a temperature relating to the electronic system;
means for determining a temperature range which includes said determined temperature;
means for determining a temperature direction;
means for determining a corresponding change in duty cycle over time, or function thereof, for said determined temperature range and determined temperature direction;
means for determining a new duty cycle based on said corresponding duty cycle change over time, or a function thereof; and
means for outputting a PWM signal with said new duty cycle.

33. A system for controlling a speed of a fan for an electronic system, comprising:
a temperature monitoring and fan control module, wherein said temperature monitoring and fan control module is configured to receive a plurality of temperature readings relating to the electronic system associated with a fan, configured for each of said plurality of received temperatures to calculate a value of a variable relating to fan speed or a function thereof corresponding to said each received temperature; configured to select a value of a variable or a function thereof which would lead to a highest fan speed out of said calculated values; and configured to output a control signal reflecting said selection.

34. A system for controlling a speed of a fan for an electronic system including a central processing unit, comprising:
a temperature monitoring and fan control module, external to the central processing unit, configured to receive a temperature relating to said electronic system; configured to check whether said temperature has a predetermined relationship with a predetermined temperature level or range; and configured to adjust at least one parameter which affects fan speed, if said temperature has a predetermined relationship;
wherein said at least one parameter is selected from a group comprising: slope of a range where a variable relating to fan speed is proportional to temperature, slope of a range where duty cycle is proportional to temperature, maximum value of a variable relating to fan speed, maximum duty cycle, minimum value of a variable relating to fan speed, minimum duty cycle, predetermined level where adaptation occurs, predetermined range where adaptation occurs, predetermined relationship to be checked, impact of time duration during which a predetermined relationship holds on adaptability, correspondence between ambient temperatures and parameters, correspondence between value of a variable relating to fan speed and temperature direction, correspondence between value of a variable relating to fan speed and temperature change, correspondence between value of a variable relating to fan speed and rate of temperature change, and correspondence between value of the variable relating to fan speed with time temperature is at a same level or range.

35. A computer program product comprising a computer useable medium having computer readable program code embodied therein for controlling a speed of a fan for an electronic system the computer program product comprising:
computer readable program code for causing the computer to determine a temperature relating to the electronic system;
computer readable program code for causing the computer to determine a change in a value of a variable relating to fan speed which corresponds to said determined temperature; and
computer readable program code for causing the computer to cause the speed of a fan to change in accordance with said determined corresponding change, if there is a nonzero determined corresponding change in a value of said variable relating to fan speed.

36. A computer program product comprising a computer useable medium having computer readable program code embodied therein for controlling a speed of a fan for an electronic system, the computer program product comprising:
computer readable program code for causing the computer to determine a temperature relating to the electronic system;
computer readable program code for causing the computer to check whether said temperature has a predetermined relationship with a predetermined temperature level or range; and
computer readable program code for causing the computer to adjust at least one parameter which affects a correspondence between temperature and change in a value of a variable relating to fan speed, if said temperature has a predetermined relationship.

37. A computer program product comprising a computer useable medium having computer readable program code embodied therein for controlling a speed of a fan in an electronic system, the computer program product comprising:
computer readable program code for causing the computer to determine a temperature relating to the electronic system;
computer readable program code for causing the computer to determine a temperature range which includes said determined temperature;
computer readable program code for causing the computer to determine a temperature direction;
computer readable program code for causing the computer to determine a corresponding change in duty cycle over time, or function thereof, for said determined temperature range and determined temperature direction;
computer readable program code for causing the computer to determine a new duty cycle based on said corresponding duty cycle change over time, or a function thereof; and
computer readable program code for causing the computer to output a PWM signal with said new duty cycle.

38. A computer program product comprising a computer useable medium having computer readable program code embodied therein for controlling a speed of a fan in an electronic system, the computer program product comprising:
computer readable program code for causing the computer to determine a plurality of temperatures relating to the electronic system which are associated with the fan;
computer readable program code for causing the computer to calculate a value of a variable relating to fan speed or a function thereof corresponding to said each determined temperature for each of said plurality of determined temperatures;
computer readable program code for causing the computer to select a value of said variable or a function thereof which would lead to a highest fan speed out of said calculated values; and
computer readable program code for causing the computer to output a control signal reflecting said selection.

39. A computer program product comprising a computer useable medium having computer readable program code embodied therein for controlling a speed of a fan for an electronic system including a central processing unit, the computer program product comprising:
computer readable program code for causing the computer to determine a temperature relating to said electronic system;
computer readable program code for causing the computer to check whether said temperature has a predetermined relationship with a predetermined temperature level or range; and
computer readable program code for causing the computer to adjust at least one parameter which affects fan speed, if said temperature has a predetermined relationship;
wherein said checking and adjusting occur outside of the central processing unit, and wherein said at least one parameter is selected from a group comprising: slope of a range where a variable relating to fan speed is proportional to temperature, slope of a range where duty cycle is proportional to temperature, maximum value of a variable relating to fan speed, maximum duty cycle, minimum value of a variable relating to fan speed, minimum duty cycle, predetermined level where adaptation occurs, predetermined range where adaptation occurs, predetermined relationship to be checked, impact of time duration during which a predetermined relationship holds on adaptability, correspondence between ambient temperatures and parameters, correspondence between value of a variable relating to fan speed and temperature direction, correspondence between value of a variable relating to fan speed and temperature change, correspondence between value of a variable relating to fan speed and rate of temperature change, and correspondence between value of the variable relating to fan speed with time temperature is at a same level or range.
